(19) United States
(12) Patent Application Publication
(10) Pub. No.: US 2009/0127700 A1
(43) Pub. Date: May 21, 2009

(54) THERMAL CONDUCTOR LIDS FOR AREA ARRAY PACKAGED MULTI-CHIP MODULES AND METHODS TO DISSIPATE HEAT FROM MULTI-CHIP MODULES

(76) Inventor: Matthew Romig, Richardson, TX (US)

Correspondence Address: TEXAS INSTRUMENTS INCORPORATED, P O BOX 655474, M/S 3999, DALLAS, TX, 75265, US

(21) Appl. No.: 11/943,328

(22) Filed: Nov. 20, 2007

(51) Int. Cl. H01L 23/36; H01L 21/56

(52) U.S. Cl. 257/712; 438/108; 257/E23.101; 257/E21.502

(57) ABSTRACT

Multi-chip modules and methods to form multi-chip modules are disclosed. A disclosed method to form a multi-chip module includes attaching a first integrated circuit to a top surface of a substrate, attaching a second integrated circuit to the top surface of the substrate, the top surface of the second integrated circuit having a top surface taller than a top surface of the first integrated circuit, and attaching a heat conductor to the top surface of the first and second integrated circuits.

### TECHNICAL FIELD

The present disclosure pertains to integrated circuits and, more particularly, to thermal conductor lids for area array packaged multi-chip modules and methods to dissipate heat from multi-chip modules.

### BACKGROUND

Consumer electronic devices in recent years have become more powerful and more integrated at the same time. To make consumer electronic devices more powerful without requiring more space, integrated circuits associated with electronic devices have integrated more functions and more controls into smaller die areas. The desire of consumers for more processing power has not abated, but instead, continues to grow. In some cases, it is desirable to interface multiple integrated circuits as a single integrated circuit In such cases, multiple integrated circuits are packaged into a multi-chip module that is incorporated into electronic devices.

Heat spreading metal lids attached directly to the die are a common solution for flip-chip packaging, however, such lids are not used in wire bond packaging because of interference with the wire bonds

### SUMMARY

Multi-chip modules and methods to form multi-chip modules are disclosed. A disclosed method to form a multi-chip module includes attaching a first integrated circuit to a top surface of a substrate and second integrated circuit to the top surface of the substrate. However, the top surface of the second integrated circuit is taller than a top surface of the first integrated circuit. In some examples, the height may be different due to different attachment techniques or the first and second integrated circuits may have different thicknesses. After attaching the second integrated circuit, a heat spreading lid is placed in contact with the top surfaces of the first and second integrated circuits. The head conductor lid includes a downwardly depending extension or a pedestal to enable the conductor to simultaneously contact the top surface of both the first and second integrated circuits. In some examples, a single heat conductor lid engages a flip chip and a wire bonded integrated circuit.

### BRIEF DESCRIPTION OF THE DRAWINGS

FIG. 1 is an illustration of an example multi-chip module.

FIG. 2 is a flowchart of an example process to form a multi-chip module.

FIGS. 3A-3F are illustrations of a multi-chip module at different stages of the example process of FIG. 2.

FIG. 4 illustrates another example multi-chip module.

FIG. 5A is a flowchart of another example process to form a multi-chip module illustrated in FIG. 5B.

FIG. 5B illustrates an example multi-chip module fabricated using the process of FIG. 5A.

FIG. 6A is a flowchart of another example process to form a multi-chip module illustrated in FIG. 6B.

FIG. 6B illustrates an example multi-chip module fabricated using the process of FIG. 6A.

FIGS. 7A-7E illustrate example multi-chip modules that may be formed by the example processes of FIGS. 2, 5A, or 6A.

To clarify multiple layers and regions, the thickness of the layers are enlarged in the drawings. Wherever possible, the same reference numbers will be used throughout the drawing(s) and accompanying written description to refer to the same or like parts. As used in this patent, stating that any part (e.g., a layer, film, area, or plate) is in any way positioned on (e.g., positioned on, located on, disposed on, or formed on, etc.) another part, means that the referenced part is either in contact with the other part, or that the referenced part is above the other part with one or more intermediate part(s) located therebetween. Stating that any part is in contact with another part means that there is no intermediate part between the two parts.

### DETAILED DESCRIPTION

Generally, multi-chip integrated modules and methods to fabricate the same will now be disclosed in detail. As used herein, a multi-chip module is a module including at least two integrated circuits that are attached to a substrate.

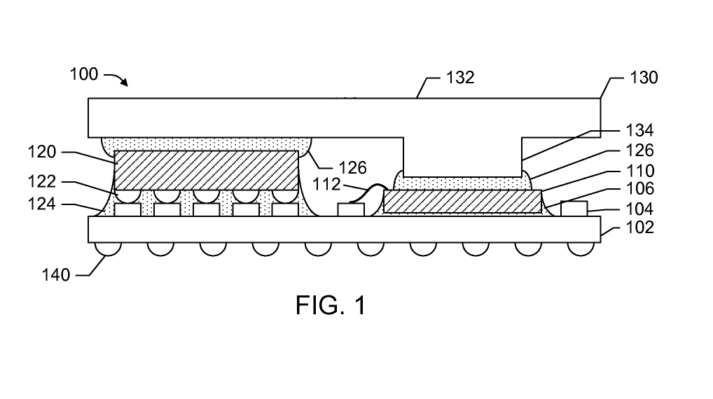

FIG. 1 illustrates an example multi-chip module 100. The multi-chip module 100 may include a flip chip and a wire bonded integrated circuit. In other examples, the multi-chip module 100 may include any number of integrated circuits attached by any suitable process (e.g., two wire bonded integrated circuits, two flip chip integrated circuits and a single wire bonded integrated circuit, etc.). In the example of FIG. 1, one or both of the integrated circuits may generate significant heat. To dissipate the heat, a single heat spreading lid structured to accommodate differences in height between the chips is used to dissipate heat from the chips.

Generally, a substrate 102 having a plurality of pads 104 supports a first integrated circuit 110 and a second integrated circuit 120. The integrated circuits 110, 120 are attached to the substrate 102 by any suitable method (e.g., flip-chip, epoxy bond, eutectic bond, etc.). Generally, the integrated circuits 110, 120 are attached based on the application. For example, if the wire bonded integrated circuit 110 is a mixed-mode analog-digital integrated circuit, it may be die bonded because the inductances of the bond wires may not substantially affect the performance of the integrated circuit 110. Still, in other examples, if the integrated circuit 120 is a high frequency device (e.g., a high-frequency wireless transceiver) that is affected by inductances associated with the bond wires, the integrated circuit 120 may be flip chipped.

In the example of FIG. 1, the example multi-chip module 100 includes two integrated circuits 110, 120 attached via different processes. In particular, the integrated circuit 110 is a wire bonded integrated circuit (i.e., die attached) and the other integrated circuit 120 is a flip chip. The wire bonded integrated circuit 110 is attached to the substrate 102 via an epoxy layer 106. After securing the integrated circuit 110 to the substrate 102 via the epoxy layer 106, at least one bond wire 112 is placed between pad(s) 104 of the substrate 102 and a contact of the integrated circuit 110. In other examples, the integrated circuit 110 may be attached directly to a pad 104 via a eutectic bond. As mentioned above, the second integrated circuit 120 of FIG. 1 is attached to the substrate 102 via a flip chip process. In an example flip chip attachment method, conductive elements 122 (e.g., a gold bump, a solder ball, etc.) are applied to contacts on the top of the integrated circuit 120. After placing the conductive elements 122, the integrated circuit 120 is flipped over and attached to the pads 104 of the substrate 102 via the conductive elements 122.

In order to conduct heat from the integrated circuits 110, 120 and protect the multi-chip module 100 from environmental influence, a lid 130 is attached to the top surface of the integrated circuits 110, 120. In the example of FIG. 1, the lid 130 is attached via an adhesive 126 (e.g., an epoxy, etc.) that is applied to the integrated circuits 110, 120. The lid 130 may be implemented by any type of material or compound (e.g., a carbon graphite, a metal, a ceramic, etc.) to conduct heat from the integrated circuits 110, 120. The lid 130 may be formed by any suitable process or any suitable combination of processes (e.g., forging, casting, machining, etc.). In the example of FIG. 1, both the lid 130 and the substrate 102 conduct heat away from the integrated circuits 110, 120, thereby cooling the integrated circuits 110, 120. The example multi-chip module 100 may also include conductive elements 140 (e.g., solder balls, a metal plate, etc.) to facilitate electrical and mechanical attachment (e.g., solder, etc.) with electronic devices or systems.

As mentioned above, the integrated circuits 110, 120 may be of different types, may be mounted differently, or both. Therefore, the top surface of the integrated circuits 110, 120 may not be planar. In other words, the top surfaces of integrated circuits 110, 120 may be at different heights relative to the substrate 102 after attachment. To accommodate their height differences, the lid 130 of the illustrated examples includes a generally planar body 132 and a raised portion 134 (e.g., a projector or a pedestal). The body 132 and the raised portion 134 may be made of the same or different materials. In other words, the body 132 and the raised portion 134 may be integrally formed or may be two or more discrete components joined together. In yet other examples, the integrated circuits 110, 120 may both be wire bonded to the substrate 102. However, in such examples, the integrated circuits 110, 120 may have different thicknesses such that their top surfaces are not planar.

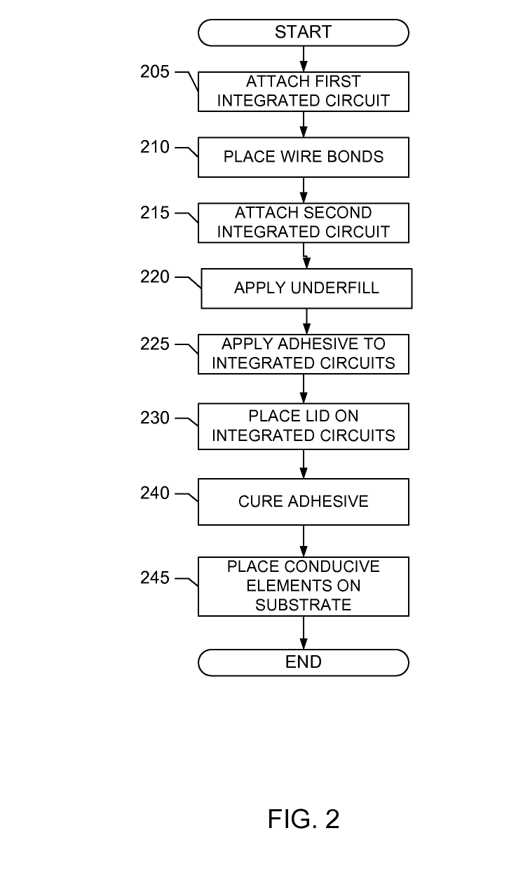

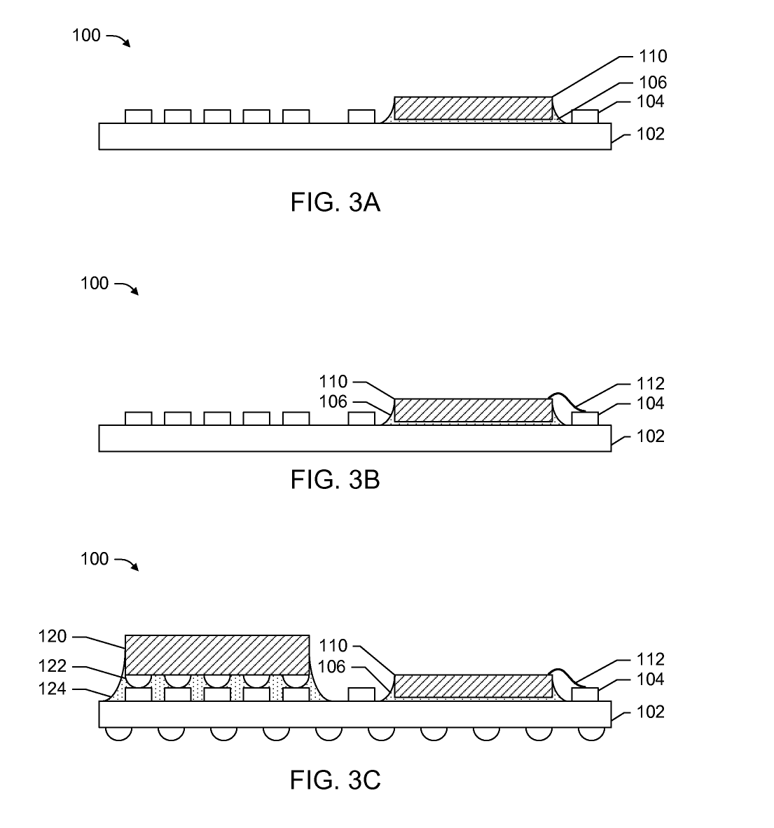

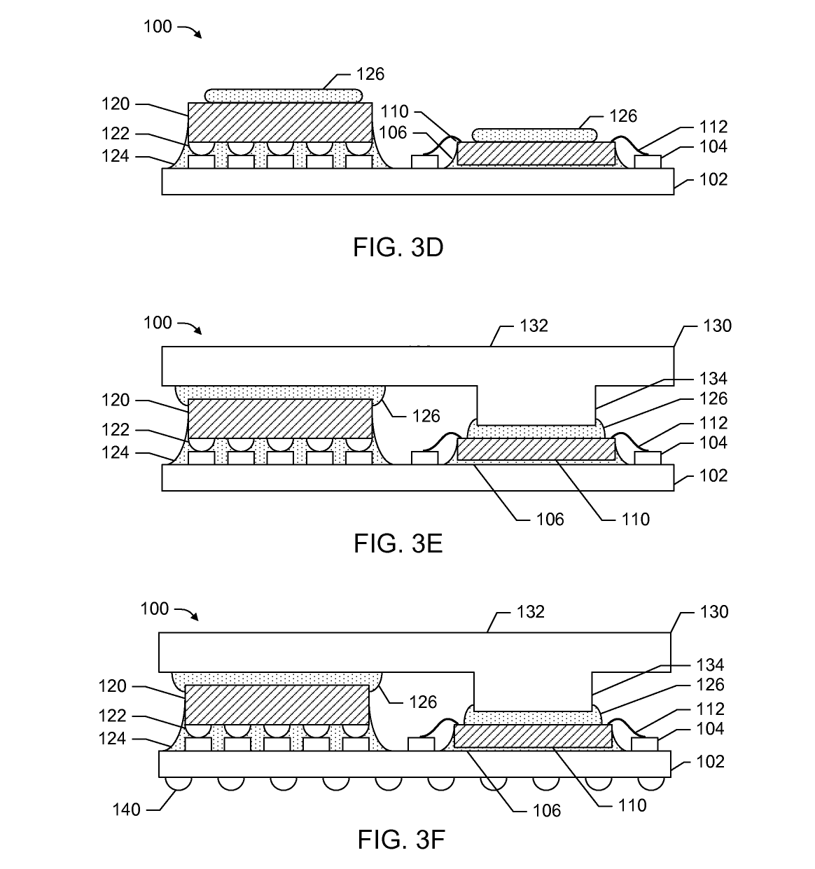

FIG. 2 illustrates an example process 200 to form the example multi-chip module 100 of FIG. 1. The example process 200 will be explained in conjunction with FIGS. 3A-3F, which illustrate the example multi-chip module 100 of FIG. 1 at different stages of the example process 200. As shown in FIG. 3A, the example process 200 begins by attaching a first integrated circuit 110 to a substrate 102 via an epoxy layer 106 (block 205). After attaching the first integrated circuit 110, as illustrated in FIG. 3B, one or more bond wires 112 are placed between pads 104 of the substrate 102 and contacts of the integrated circuit 110 (block 210). The bond wires 112 may be implemented by any suitable material (e.g., gold, aluminum, copper, etc.) and may be bonded be any bond type (e.g., wedge, stitch, etc.).

Returning to FIG. 2, a second integrated circuit 120 is attached to the substrate 102 via any suitable process (block 215). In the example of FIG. 3C, the second integrated circuit 120 is attached via a flip chip process. Thus, the contacts of the second integrated circuit 120 are attached to the pads of the substrate via conductive element(s) 122 (e.g., a solder ball, a gold bump, etc.). After attaching the second integrated circuit 120, an underfill 124 is placed between the substrate 102 and the second integrated circuit 120 (block 220). The underfill 124 is generally a non-conductive adhesive material (e.g., an epoxy, etc.) that fills the space between the second integrated circuit 120 and the substrate 102 to protect the conductive elements 122 that are attached to the pads 104.

In the examples of FIGS. 2 and 3D, after the first and second integrated circuits 110, 120 are placed on the substrate 102, an adhesive 126 (e.g., a thermally conductive epoxy, etc.) is applied to the top surface of the integrated circuits 110, 120 (block 225). After placing the adhesive 126 on the integrated circuits 110, 120, a lid 130 is placed in contact with the integrated circuits 110, 120 via the adhesive 126 (block 230). In the example of FIG. 3E, the adhesive 126 is selected to be thermally conductive, thereby placing the thermally conductive lid 130 in thermal contact with the integrated circuits 110, 120. The adhesive 126 is cured by any suitable process (e.g., heat, time, etc.) such that it solidifies and secures the lid 130 to the integrated circuits 110, 120 (block 240). As illustrated in FIG. 3F, conductive elements 140 may be placed on a bottom surface of the substrate 102 (block 245) to facilitate electrical and mechanical (e.g., solder) attachment of the multi-chip module 100 to a circuit board or the like.

Although the foregoing describes a particular sequence of operations, the sequence of operations of the example process 200 may be changed. For example, the stages of the process may be rearranged, combined, or divided. Alternatively or additionally, additional stages, processes or operations may be added. For example, additional devices (e.g., circuits, capacitors, inductors, resistors, etc.) may be added to the substrate 102. In such examples, an additional process step to attach the additional devices to the substrate may be needed (e.g., a solder reflow). Alternatively or additionally, some or all of the materials and illustrations described above may be changed. For example, the substrate 102 may be implemented by a leadframe land grid array, thereby having conductive elements 140 (i.e., leads, contacts, etc.) already formed on the substrate 102.

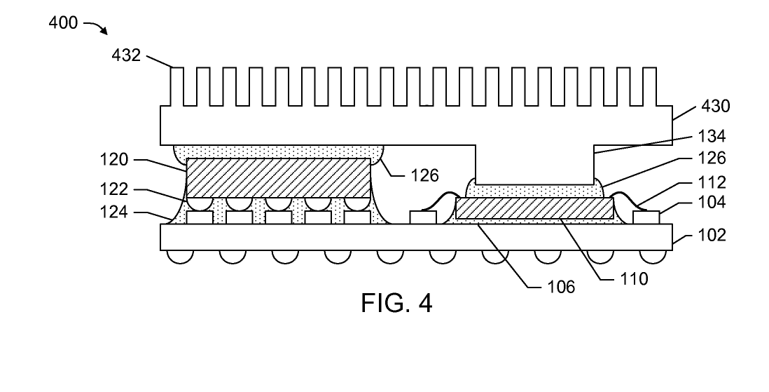

FIG. 4 illustrates another example multi-chip module 400. In the example of FIG. 4, the lid 430 includes a non-planar surface 432. The non-planar surface 432 has a larger surface area than the planar surface of the example lid 130 of FIG. 1. Because of the increased surface area of the lid 430, the lid 430 conducts heat to a cooler medium (e.g., air) at a greater rate than the planar lid 130 of FIG. 1, thereby cooling the integrated circuits 110, 120 at a greater rate. In the example of FIG. 4, the non-planar surface 432 is implemented by evenly spaced projections having rectangular cross-sections. However, a non-planar surface may be implemented with any type of structure, shape, pattern, configuration, and so forth.

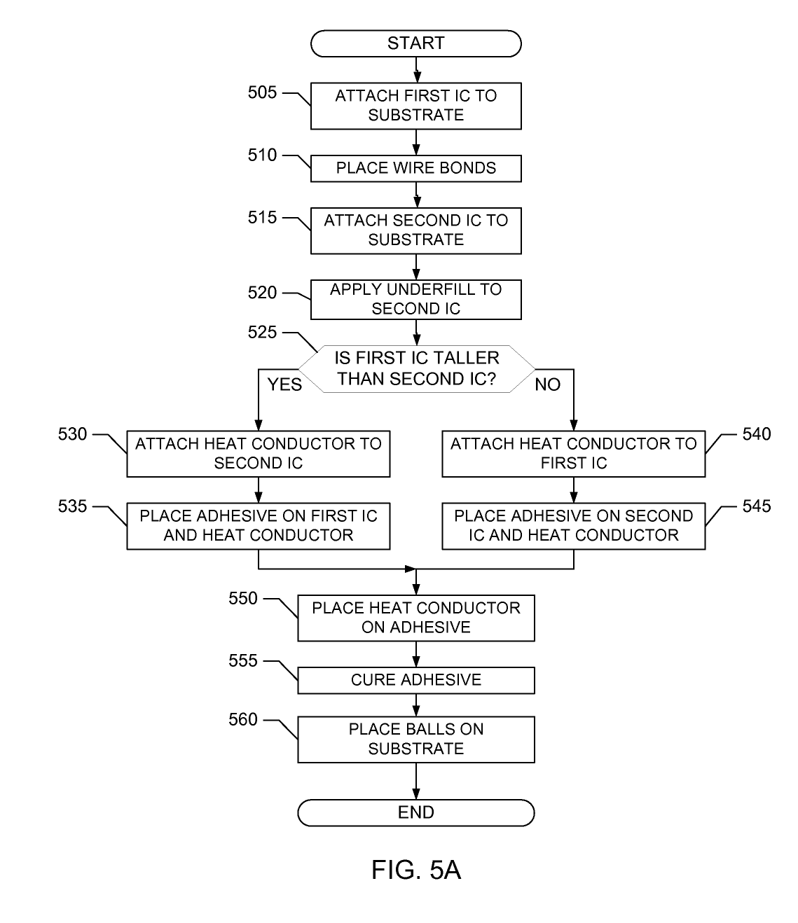

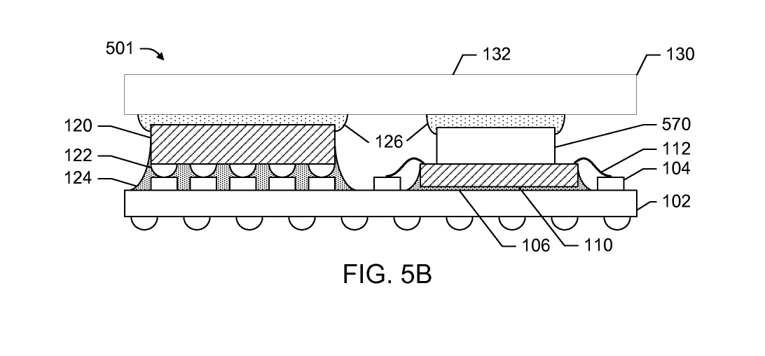

FIG. 5A illustrates another example process 500 to form an example multi-chip module 501 illustrated in the example of FIG. 5B. The example process 500 begins by attaching a first integrated circuit 110 to a substrate 102 via an epoxy layer 106 (block 505). After attaching the first integrated circuit 110, as illustrated in FIG. 5B, one or more bond wires 112 are placed between one or more pads 104 of the substrate 102 and one or more contacts of the integrated circuit (block 510). The bond wires 112 may be implemented by any suitable material (e.g., gold, aluminum, copper, etc.) and any type of bond (e.g., wedge, stitch, etc.). As illustrated in FIG. 5B, a second integrated circuit 120 is attached to the substrate 102 via a flip chip process, thereby attaching the contacts of the second integrated circuit to the pads 104 via conductive elements 122 (e.g., a solder ball, a gold bump, etc.). After attaching the second integrated circuit 120, an underfill 124 is placed between the substrate 102 and the second integrated circuit 120 (block 520).

After the first and second integrated circuits 110, 120 are placed on the substrate 102, the example process 500 determines if the height of the top surface of the first integrated circuit 110 exceeds the height of the top surface of the second integrated circuit (block 525). If the top surface of the first integrated circuit 110 is higher than the top surface of the second integrated circuit 120, then a heat conductor 570 (e.g., a metal slug, a carbon graphite slug, a silicon spacer, etc.) is attached via any process (e.g., die bond, epoxy bond, eutectic bond, an adhesive, etc.) to the top surface of the second integrated circuit 120 (block 530). After placing the heat conductor 570, an adhesive 126 is applied to the top surface of the heat conductor 570 and the integrated circuit 110 (block 535). However, as illustrated in the example of FIG. 5B, if the top surface of the first integrated circuit 110 is lower than the top surface of the second integrated circuit 120, then the heat conductor 570 is attached via any suitable process to the top surface of the first integrated circuit 110 (block 540). After placing the heat conductor 570, an adhesive 126 is applied to the top surface of the heat conductor 570 and the integrated circuit 120 (block 545).

After placing the adhesive 126 on the either of the integrated circuits 110, 120 and the heat conductor 570, the lid 130 is placed above the integrated circuits 110, 120 and the heat conductor 570 (block 550). The adhesive 126 is cured by any suitable process (e.g., heat, time, etc.) and solidifies, thereby securing the lid 130 to the integrated circuits 110, 120 and forming the multi-chip module 501 (block 565). Conductive elements 140 may be placed on a bottom surface of the substrate 102 (block 560) to facilitate electrical and mechanical (e.g., solder) attachment of the multi-chip module 501 to a circuit board of the like. The example process 500 of FIG. 5A ends after the conductive elements 140 are placed.

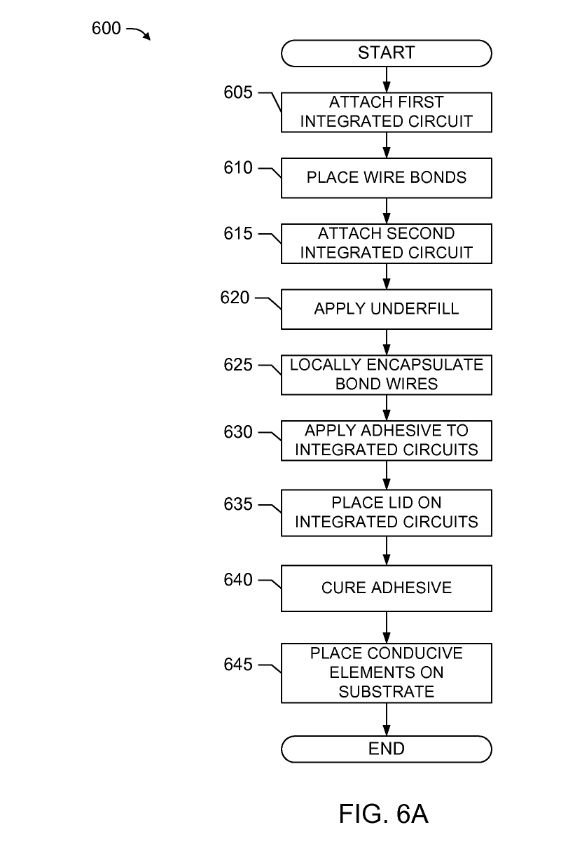

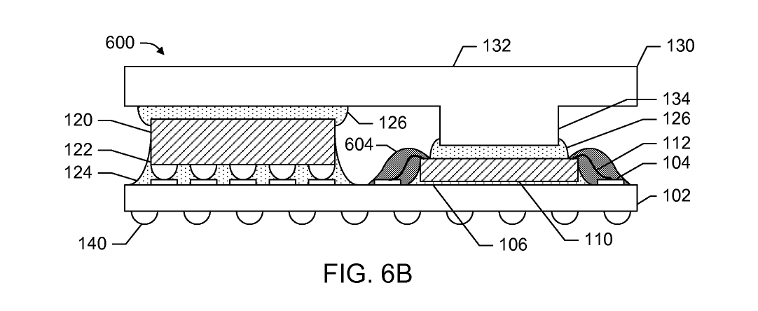

FIG. 6A illustrates yet another example process 600 to form the example multi-chip module 601 of FIG. 6B. The example process 600 begins by attaching the integrated circuit 110 to the substrate 102 (block 605). Next, bond wires 112 are placed between the contacts of the integrated circuit 110 and the pads 104 (block 610). After placing the bond wires 112, the second integrated circuit 120 is attached to the substrate 102 (block 615) and an underfill 124 is applied to the second integrated circuit 120 (block 620). In the example of FIG. 6B, the bond wires 112 are encapsulated in a local encapsulant 604, which is implemented via any suitable material (e.g., an epoxy resin) (block 625). In such examples, the local encapsulant 604 may partially or completely encapsulate the bond wires 112, thereby protecting the bond wires 112 from damage, which can lead to electrical failure of the multi-chip module 600, reliability failure, or both.

The example process 300 next applies an adhesive 126 to the top surface of the integrated circuits 110, 120 (block 630) and the lid 130 is then placed on the integrated circuits (block 635). After placing the lid 130, the adhesive 126 is cured (block 640) and secures the lid to the integrated circuits 110, 120. Then, conductive elements 140 are placed on the bottom surface of the substrate 102 for mechanical and electrical attachment to other devices and systems (block 645). After placing the conductive elements 140, the example process 600 ends.

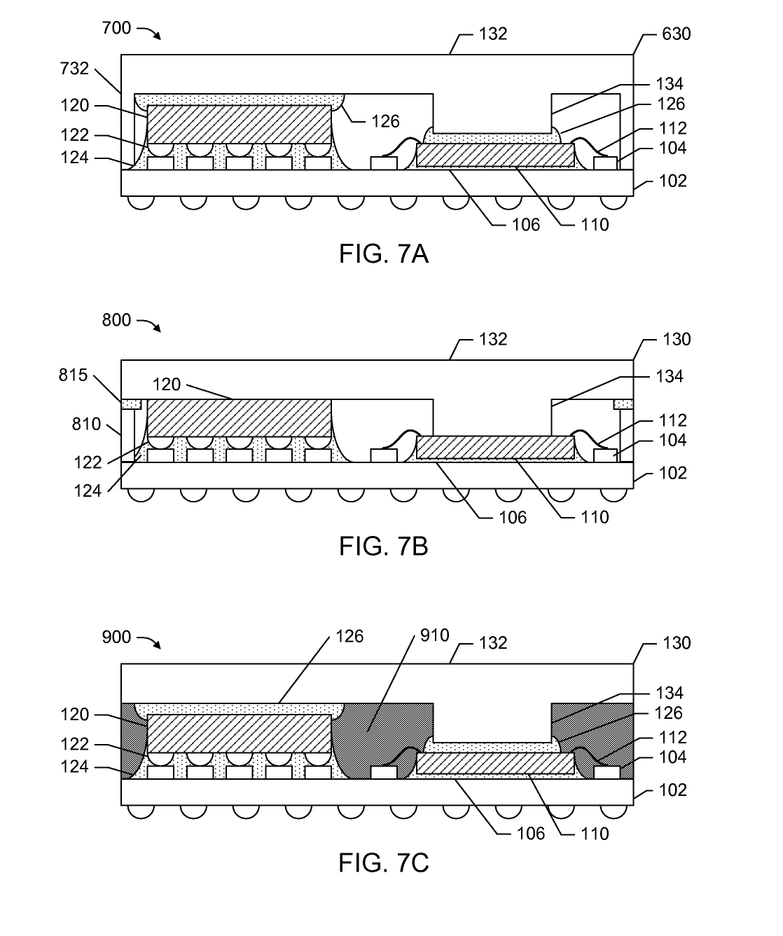

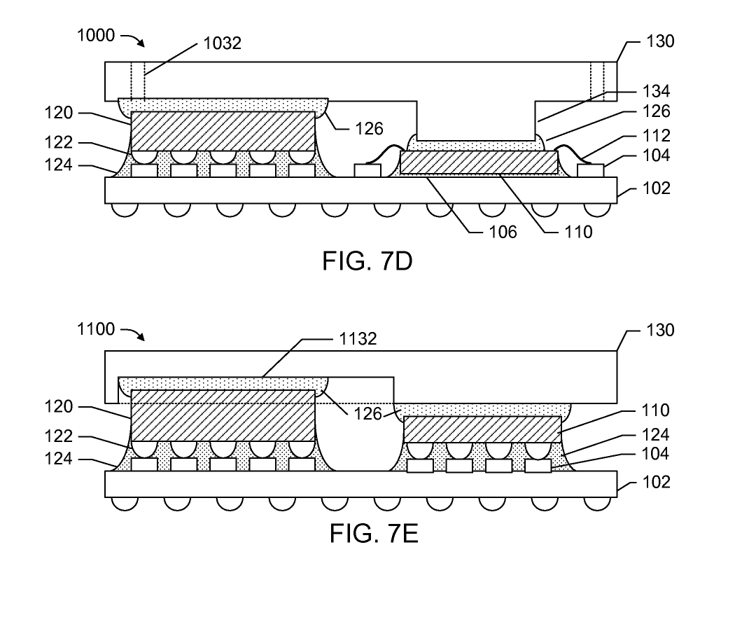

FIGS. 7A-7E illustrate other example multi-chip modules 700, 800, 900, 1000, and 1100. In the example of FIG. 7A, the example multi-chip module 700 includes a lid 730 having flanges 732 extending downward from the edges of the lid 730. In the example of FIG. 7A, the flanges 732 substantially encapsulate the integrated circuits 110, 120 to protect the contents of the multi-chip module 700 from the sides.

The example multi-chip module 800 of FIG. 6B is similar to the multi-chip module 600 of FIG. GA. However, the multi-chip module 800 includes at least one spacer 810 on at least one edge of the substrate 102. The spacers 810 of the illustrated example are configured to ensure coplanarity of the lid 130. In other examples, an adhesive 815 may be applied to the lid 130. The lid 130 is then attached to the spacer 810 via the adhesive 815. As a result, the lid 130 is secured to the spacer 810 and the lid 130 is placed directly in contact with the integrated circuits 110, 120 without an intervening adhesive. In such examples, a thermal compound (not shown) may be applied to the integrated circuits 110, 120 to fill in microvoids between the lid 130 and the integrated circuits 110, 120 to improve thermal performance.

FIG. 7C illustrates another example multi-chip module 900 that is similar to the multi-chip module 100. However, in the example of FIG. 7C, a mold compound 910 (e.g., an epoxy resin, etc.) is configured to substantially fill the multi-chip module 100 between the substrate 102 and the lid 130. In the illustrated example, the mold compound 910 is a rigid material and protects the contents of the multi-chip module 900.

FIG. 7D illustrates another example multi-chip module 1000. The multi-chip module 1000 is similar to the multi-chip module 100. However, in the example of FIG. 6D, the lid 1030 includes an attachment structure 1032 (e.g., a threaded hole, a hook, etc.) to receive a fastener to facilitate attachment of an external cooling device (e.g., a heat sink, a fan, etc). In the example of FIG. 7D, the attachment structure 1032 is a threaded hole that receives a fastener (e.g., a screw, etc.), thereby allowing a cooling device to be attached directly to the multi-chip module 1000. By allowing the cooling device to attach directly to the lid 1030, additional force is not exerted on the integrated circuits 110, 120, thereby protecting the integrated circuits 110, 120 from mechanical damage, electrical damage, or both.

FIG. 7E illustrates another example multi-chip module 1100. The multi-chip module 1100 is similar to the multi-chip module 100. However, rather than including a projection or extension 134, in the example of FIG. 6E, the lid 1130 includes a recessed portion 1132 to accommodate the height differences between the integrated circuits 110, 120. The contact between the thermally conductive lid 1130 to each of the integrated circuits 110, 120 improves thermal performance of the multi-chip module 1100. In such examples, the lid 1130 may be cheaper to manufacture than the lid 130.

Multi-chip modules having a thermally conductive lid to cool two or more integrated circuits of different heights and methods of fabricating the same have been disclosed. In the above examples, the lid provides improved thermal performance of the integrated circuits by removing heat, thereby allowing a plurality of integrated circuits that consume significant power to be packaged into a single multi-chip module. In addition, the lid provides protection to bond wires associated with the integrated circuits, thereby increasing the reliability of the multi-chip module. The inclusion of such a lid into existing fabrication processes is an inexpensive process change.

For multi-chip modules including a wire bonded integrated circuit, the above described thermal spreading lids can be employed to dissipate heat, even when the wire bonded integrated circuit is disposed next to an integrated circuit of a different height (e.g., a flip chip). This approach allows the wire bonded integrated circuit and the entire package to use more power with less temperature rise. Prior to this disclosure, there was no known single method to use a flip chip next to a wire bonded integrated circuit in the same multi-chip module with an acceptable thermal solution.

The above described approaches provide an alternative approach to provide protection for wire bonds in a multi-chip module including a flip chip and a wire bonded integrated circuit. A typical transfer mold process (which is commonly used for wire bonded integrated circuits) will not work with singulated substrates, especially if a flip chip is located on the substrate. In addition, though the described examples include a single pedestal to thermally contact a second integrated height, any number of integrated circuits may be included in the multi-chip module and any number of pedestals may be implemented on the heat spreading lid to thermally contact each integrated circuit.

Although certain methods, apparatus, and articles of manufacture have been described herein, the scope of coverage of this patent is not limited thereto. On the contrary, this patent covers all apparatus, methods and articles of manufacture fairly falling within the scope of the appended claims either literally or under the doctrine of equivalents.

What is claimed is:

1. A method of forming a multi-chip module, comprising:
attaching a first integrated circuit to a top surface of a substrate;
attaching a second integrated circuit on the top surface of the substrate, the top surface of the second integrated circuit being higher above the substrate that a top surface of the first integrated circuit; and
attaching a heat conductor lid having an undersurface structure to the top surface of the first integrated circuit and the top surface of the second integrated circuit.

2. A method as described in claim 1, wherein the heat conductor lid is attached to the first and second integrated circuits via an adhesive.

3. A method as described in claim 1, wherein the undersurface structure of the heat conductor lid is in thermal contact with the first integrated circuit.

4. A method as defined in claim 1, further comprising attaching conductive bumps to a bottom surface of the substrate.

5. A method as defined in claim 1, wherein the heat conductor substantially covers the first and second integrated circuits.

6. A method as defined in claim 5, wherein a flange of the heat conductors substantially encapsulates the first and second integrated circuits.

7. A method as defined in claim 1, wherein a mold substantially encapsulates the first and second integrated circuits.

8. The method as defined in claim 1, wherein the first integrated circuit is a flip chip integrated circuit and the second integrated circuit is a wire bonded integrated circuit.

9. The method as defined in claim 1, wherein the first integrated circuit is a wire bonded integrated circuit, and wherein a mold locally encapsulates bond wires of the first integrated circuit.

10. A multi-chip module, comprising:
a first integrated circuit attached to a substrate, the first integrated circuit having a first height relative to the substrate;
a second integrated circuit attached substrate, the second integrated circuit having a second height relative to the substrate; and
a heat conductor having an undersurface structure to thermally contact both the first and second integrated circuits.

11. The multi-chip module as defined in claim 10, wherein the heat conductor is attached to the first and second integrated circuits via an adhesive.

12. The multi-chip module as defined in claim 10, wherein the undersurface structure comprises a raised portion that is to be in thermal contact with the first integrated circuit.

13. The multi-chip module as defined in claim 10, wherein the heat conductor includes a recessed portion that is to be in thermal contact with the first integrated circuit.

14. The multi-chip module as defined in claim 10, further comprising conductive bumps attached to a bottom surface of the substrate.

15. The multi-chip module as defined in claim 9, wherein the heat conductor substantially covers the first and second integrated circuits.

16. The multi-chip module as defined in claim 15, wherein the heat conductor includes flanges to substantially encapsulate the first and second integrated circuits.

17. The multi-chip module as defined in claim 10, wherein a mold substantially encapsulates the first and second integrated circuits.

18. The multi-chip module as defined in claim 10, wherein the first integrated circuit is a flip chip and the second integrated circuit is a wire bonded integrated circuit.

19. The multi-chip module as defined in claim 10, wherein the heat conductor includes a non-planar surface that is exposed to the environment.

20. The multi-chip module as defined in claim 10, wherein the undersurface structure comprises a recessed portion.

21. The multi-chip module as defined in claim 10, wherein the substrate includes flanges, and wherein the heat conductor is attached to the flanges.

22. The multi-chip module as defined in claim 10, wherein the heat conductor includes at least one attachment structure to receive a fastener.

23. The multi-chip module as defined in claim 10, wherein the undersurface structure is joined to the heat conductor.

24. The multi-chip module as defined in claim 10, wherein the undersurface structure is integral to the heat conductor.

25. The multi-chip module as defined in claim 10, wherein the first integrated circuit is a wire bonded integrated circuit, and wherein a mold locally encapsulates bond wires of the first integrated circuit.
